(19) United States
(12) Patent Application Publication
(10) Pub. No.: US 2026/0101656 A1
(43) Pub. Date: Apr. 9, 2026

(54) Display Device

(71) Applicant: LG Display Co., Ltd., Seoul (KR)

(72) Inventors: Hoonsok Son, Seoul (KR); Minki Kim, Anyang-si (KR)

(21) Appl. No.: 19/272,298

(22) Filed: Jul. 17, 2025

(30) Foreign Application Priority Data
Oct. 4, 2024 (KR) 10-2024-0134580

(51) Int. Cl. H10K 59/38

(52) U.S. Cl. CPC H10K 59/38

(57) ABSTRACT

A display device includes a first substrate including a plurality of sub-pixels; each first electrode disposed on each of the plurality of sub-pixels; a light-emitting layer disposed on the first electrodes a second electrode disposed on the light-emitting layer, and a color conversion structure disposed over the plurality of sub-pixels, wherein the color conversion structure has different thicknesses in each of the sub-pixels.

### CROSS-REFERENCE TO RELATED APPLICATION

This application claims priority from Republic of Korea Patent Application No. 10-2024-0134580 filed on Oct. 4, 2024, which is hereby incorporated by reference its entirety.

### BACKGROUND

### Field

The present disclosure relates to a display device for displaying an image.

### Description of Related Art

A display device is applied to various electronic devices such as a television (TV), a mobile phone, a laptop, and a tablet. To this end, research to develop a smaller, lighter, and less power consuming display device is being conducted.

Recently, as a demand for a head mounted display (HMD) including the display device increases, research thereon is also increasing. The head mounted display is an image display device that uses a glasses or helmet-type device to allow an image to be focused at a close distance to user's eyes.

The head mounted display may implement virtual reality (VR) or augmented reality (AR). The virtual reality (VR) has an advantage of allowing even an image of 1-inch size to be viewed in 60-inch size because of excellent user immersion. To this end, the head mounted display is applied with a small display device having ultra-high resolution.

### SUMMARY

In a case of a small display device with a high resolution, it is difficult to implement a light-emitting layer using a fine metal mask because of a narrow pixel spacing.

In addition, when a color filter is used in a small display device of the high resolution, a semiconductor process using expensive equipment is required, and thus the number of process steps and a manufacturing cost are increased. However, when the color filter is used and as the resolution becomes higher, a change in the line width or a deviation of the position of the color filter from a correct position occur. Thus, it is difficult to form a fine pattern. Accordingly, there is a problem in that color mixing or light leakage between the sub-pixels may occur.

Accordingly, the inventors of the present disclosure have invented a display device capable of constructing dense pixels to realize a ultra-high resolution without using a color filter through various experiments.

A purpose of an embodiment of the present disclosure is to provide a display device in which the color filter is not employed to simplify a process and not to employ an expensive equipment, thereby preventing the increase in the number of process steps and the increase in the manufacturing cost. Thus, the display device lacks a color filter.

In addition, a purpose of the present disclosure is to provide a display device including sub-pixels that emit light of different colors without using a color filter.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In one embodiment, a display device comprises: a first substrate including a plurality of sub-pixels; a plurality of first electrodes, each of the plurality of first electrodes on a corresponding sub-pixel from the plurality of sub-pixels; a light-emitting layer on the plurality of first electrodes; a second electrode on the light-emitting layer, and a color conversion structure over the plurality of sub-pixels, the color conversion structure having different thicknesses in each of the plurality of sub-pixels.

In one embodiment, a display device comprises: a substrate; a plurality of transistors on the substrate; a plurality of light-emitting elements electrically connected to the plurality of transistors, the plurality of light-emitting elements including a first light-emitting element and a second light-emitting element that emit light of a same color; and a color conversion structure on the plurality of light-emitting elements, the color conversion structure including metal and comprising: a first portion on the first light-emitting element and having a first thickness, the first portion converting the light emitted by the first light-emitting element into a first color; and a second portion on the second light-emitting element and having a second thickness that is different from the first thickness, the second portion converting the light emitted by the second light-emitting element into a second color that is different from the first color.

According to the embodiment of the present disclosure, the color filter that requires the use of the expensive equipment is absent in the small display device with the ultra-high resolution, such that the number of the process steps and the manufacturing cost may be reduced.

In addition, omitting the color filter may allow the process to be simplified, and thus the process optimization may be achieved. Accordingly, production energy may be reduced.

In addition, not using the color filter may result in preventing the occurrence of the pixel defect due to the pattern defect of the color filter.

According to an embodiment of the present disclosure, the wavelength range of light emitted from the light-emitting layer may be controlled using the color conversion structure, thereby emitting light beams of different colors from areas corresponding to different sub-pixels.

In addition, according to an embodiment of the present disclosure, a component of a light-emitting element acts as a component of the color conversion structure, such that an entire thickness of the display device may be reduced and the manufacturing process may be simplified.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

FIG. 1 is a plan view of a display device according to an embodiment of the present disclosure.

FIG. 2 is a plan view illustrating a unit pixel according to an embodiment of the present disclosure.

FIG. 3 is a cross-sectional view taken along a line I-I′ in FIG. 2 according to a first embodiment of the present disclosure.

FIG. 4 is a graph showing transmittances through different spacings between first and third layers of a color conversion structure in different areas corresponding to first to third sub-pixels in accordance with the first embodiment of the present disclosure.

FIG. 5 is a cross-sectional view along a line I-I′ in FIG. 2 according to a second embodiment of the present disclosure.

FIG. 6 is a graph showing transmittances through different spacings between first and third layers of a color conversion structure in different areas corresponding to first to third sub-pixels in accordance with the second embodiment of the present disclosure.

FIG. 7 is a cross-sectional view along a line I-I′ in FIG. 2 according to a third embodiment of the present disclosure.

FIG. 8 is a cross-sectional view along a line I-I′ in FIG. 2 according to a fourth embodiment of the present disclosure.

FIGS. 9 to 11 show a head mounted apparatus including a display device according to an embodiment of the present disclosure.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list.

In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Description.

In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

A head mounted display implements an image in an enlarged manner at a close distance to user's eyes. Accordingly, to manufacture a small display device including the head mounted display, a technology of ultra-high resolution equal to or greater than 3000 PPI is required. The small display device have a pixel size significantly smaller than a size of a pixel applied to a mobile phone or a large display device. For example, the pixel size of the mobile phone or the large display device is tens of μm to hundreds of μm, but the pixel size of the small display device is several μm. In addition, the small display device should have ultra-high resolution while having the small pixel size to implement a clear image in front of the user's eyes.

In such a small display device to which the ultra-high resolution technology is applied, because sub-pixels are densely arranged, a transistor may be formed by applying a complementary metal oxide semiconductor (CMOS) process to realize a transistor having a smaller size than a thin film transistor (TFT).

In addition, in the small display device to which the ultra-high resolution technology is applied, because the sub-pixels are densely arranged, it is difficult to implement a light-emitting layer in a deposition method using a fine metal mask (FMM).

Accordingly, as one of methods for placing the light-emitting layer on the sub-pixels, a method for forming the light-emitting layer with an organic material that emits white light and extracting a different color from the white light for each sub-pixel via a color filter may be considered.

A color filter pattern is formed using a negative type photoresist and an exposure device. The positive type photoresist has excellent resolution, and thus has an advantageous property in making a fine pattern. However, in a small display device to which ultra-high resolution technology is applied, sub-pixels are densely arranged, such that it is difficult for light for exposure to reach a target position in the process of forming the color filter. As a result, a method of forming the color filter using the positive type photoresist is highly likely to generate a residual film of the photoresist. Accordingly, the color filter is formed using a negative type photoresist.

However, when the negative type photoresist is subjected to developing with a developer, a solvent may melt and penetrate into a light exposed portion thereof which may swell. Then, a portion that should not be patterned into the color filter pattern may be patterned. Thus, it is difficult to implement a fine pattern. For example, there may be a problem in that the line width of the color filter changes or the position of the color filter deviates from the correct position. Accordingly, color mixing may occur between the sub-pixels, or a light leakage defect between the sub-pixels may occur.

Accordingly, an embodiment of the present disclosure may provide a display device in which different sub-pixels are capable of emitting light beams of different colors without using a color filter. Thus, the display device lacks a color filter.

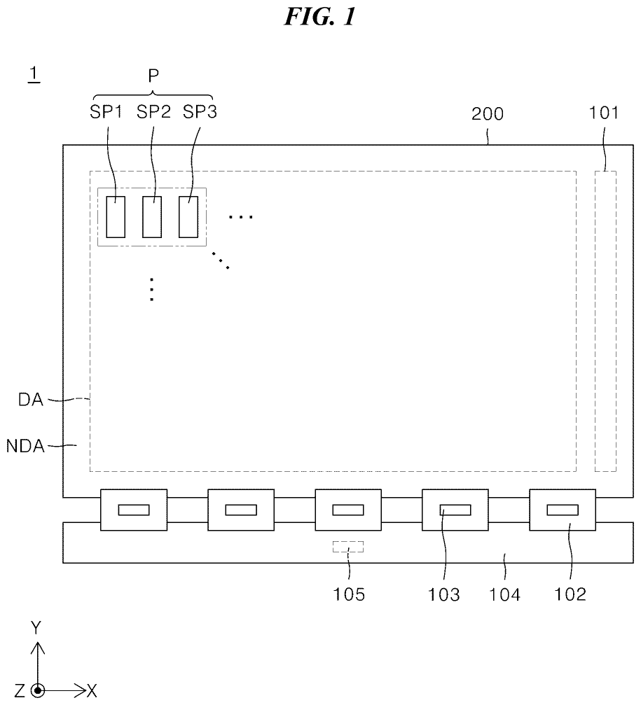

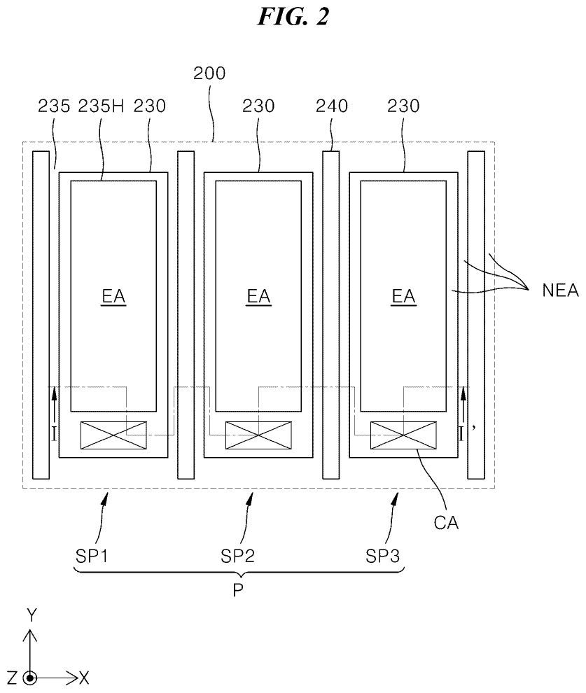

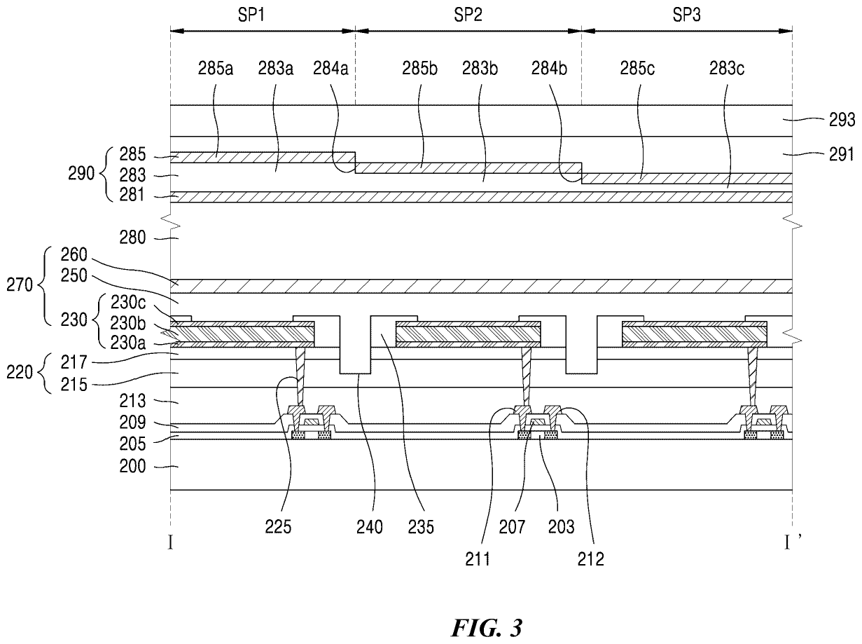

FIG. 1 is a plan view of a display device according to an embodiment of the present disclosure. FIG. 2 is a plan view illustrating a unit pixel according to an embodiment of the present disclosure. FIG. 3 is a cross-sectional view taken along a line I-I′ in FIG. 2 according to an embodiment of the present disclosure. FIG. 2 illustrates only three sub-pixels (for example, first to third sub-pixels SP1, SP2, and SP3) for convenience of description, but the present disclosure is not limited thereto.

Referring to FIGS. 1 to 3, the display device 1 according to embodiments of the present disclosure may include a first substrate 200 including a display area DA and a non-display area NDA located outside the display area DA.

The display area DA may be an area in which an image is displayed. The non-display area NDA may be an area in which no image is displayed. The non-display area NDA may be located in a peripheral area (or an edge area) of the first substrate 200, but the present disclosure may not be limited thereto. For example, an area other than a light-emitting area EA (for example, as shown in FIG. 2) in which light is emitted to the outside on the display area DA may be referred to as the non-display area DNA.

A plurality of pixels P may be disposed in the display area DA. The image may be displayed in the display area DA via the plurality of pixels P. Various lines, circuits, and the like for operating the plurality of pixels P of the display area DA may be disposed in the non-display area NDA. For example, driving circuits including a gate driving circuit and a data driving circuit may be disposed in the non-display area NDA. Several drivers 101 for driving the display area DA may be disposed in the non-display area NDA. For example, the driver 101 may include a gate driver and a data driver, but the present disclosure may not be limited thereto.

A flexible circuit board (for example, flexible printed circuit board) 102 and a printed circuit board 104 may be disposed at an edge of at least one side of the non-display area NDA. For example, the flexible circuit board 102 may include a plurality of flexible printed circuit boards, but the present disclosure may not be limited thereto. An integrated circuit chip 103 may be disposed on the flexible circuit board 102. One side of the flexible circuit board 102 may be coupled to the first substrate 200, and the other side thereof may be coupled to the printed circuit board 104 and provide power and signals for driving a light-emitting element supplied from the printed circuit board 104 to the display area DA of the first substrate 200. For example, the signal for driving the light-emitting element may include a high potential voltage, a low potential voltage, a scan signal, a data signal, or the like.

The printed circuit board 104 may supply the signal to the integrated circuit chip 103 disposed on the flexible circuit board 102. Various components for supplying the various signals to the integrated circuit chip 103 may be disposed on the printed circuit board 104. For example, the printed circuit board 104 may include a timing controller 105.

Each of the plurality of pixels P of the display area DA may be composed of a plurality of sub-pixels (for example, first to third sub-pixels SP1, SP2, and SP3). The plurality of sub-pixels (for example, the first to third sub-pixels SP1, SP2, and SP3) may be arranged in an array on the display area DA. For example, the plurality of sub-pixels (for example, the first to third sub-pixels SP1, SP2, and SP3) may be spaced apart from each other in a first direction and in a second direction intersecting the first direction on the display area DA to form a matrix arrangement. The first direction may be an X-axis direction or a row direction of the first substrate 200, and the second direction may be a Y-axis direction or a column direction of the first substrate 200. However, the present disclosure may not be limited thereto, and an arrangement order and an arrangement direction of the first to third sub-pixels SP1, SP2, and SP3 may be variously changed.

Referring to FIGS. 2 and 3, the plurality of sub-pixels (for example, the first to third sub-pixels SP1, SP2, and SP3) may be disposed on the display area DA of the first substrate 200.

A plurality of light-emitting areas EA may be located to respectively correspond to the first to third sub-pixels SP1, SP2, and SP3. A first light-emitting area EA may be located in a first sub-pixel SP1, a second light-emitting area EA may be located in a second sub-pixel SP2, and a third light-emitting area EA may be located in a third sub-pixel SP3.

The plurality of light-emitting areas EA are defined by a bank 235 including bank holes 235H. The bank hole 235H may be an opening in the bank 235 that exposes the light-emitting area EA. That is, areas exposed without being covered with the bank 235 may be the plurality of light-emitting areas EA.

A plurality of first electrodes 230 are disposed to respectively correspond to the plurality of sub-pixels SP1, SP2, and SP3. The plurality of first electrodes 230 may be disposed respectively in the first to third sub-pixels SP1, SP2, and SP3 to be spaced apart from each other.

A portion of the first electrode 230 exposed by the bank hole 235H of the bank 235 may be defined as a light-emitting area EA. For example, a first light-emitting area EA may be defined by the bank hole 235H in the first sub-pixel SP1, a second light-emitting area EA may be defined by the bank hole 235H in the second sub-pixel SP2, and a third light-emitting area EA may be defined by the bank hole 235H in the third sub-pixel SP3.

Trenches 240 extending in the second direction (for example, the Y-axis direction) may be defined in boundary areas between the plurality of sub-pixels (for example, the first to third sub-pixels SP1, SP2, and SP3). The trenches 240 may be disposed between the first sub-pixel SP1 and the second sub-pixel SP2 adjacent to each other, between the second sub-pixel SP2 and the third sub-pixel SP3 adjacent to each other, and between the third sub-pixel SP3 and the first sub-pixel SP1 adjacent to each other. For example, the trench 240 may have a length greater than a length of each of the plurality of light-emitting areas EA. However, the present disclosure is not limited thereto. A trench may extend through an entire thickness of the bank 235.

The first electrode 230 of each of the plurality of sub-pixels SP1, SP2, and SP3 may be connected to at least one transistor disposed on the first substrate 200 via each contact area CA. That is, each first electrode 230 is connected to a corresponding transistor, for example. Hereinafter, a description will be made with reference to FIG. 3.

The display device according to an embodiment of the present disclosure may be of one of a top emission type and a bottom emission type, depending on a direction in which light emitted from a light-emitting layer is emitted.

Hereinafter, referring to FIG. 3, a description of the first embodiment of the present disclosure will be made based on the top emission type by way of example.

Referring to FIG. 3, the transistor may be disposed on the first substrate 200. The first substrate 200 may include a silicon wafer (or be formed of silicon wafer). In an embodiment, the first substrate 200 may include glass or plastic (or be formed of glass or plastic).

On the first substrate 200, a driving circuit including various signal lines, transistors, a capacitor, and the like may be disposed for each of the first to third sub-pixels SP1, SP2, and SP3. The signal lines may include a gate line, a data line, a power line, and a reference line, and the transistors may include a switching transistor and a driving transistor. For example, the switching transistor and the driving transistor may be formed on the first substrate 200 using a complementary metal oxide semiconductor (CMOS) process. In an embodiment of the present disclosure, a driving transistor is illustrated for convenience of description.

The switching transistor is switched in response to a gate signal supplied to the gate line and supplies a data voltage supplied from the data line to the driving transistor, and selects the first to third sub-pixels SP1, SP2, and SP3. The driving transistor serves to drive the light-emitting element by supplying power to the first electrode 230 of the sub-pixel SP1, SP2, and SP3 selected from the switching transistor.

The capacitor serves to maintain the data voltage supplied to the driving transistor for one frame. Electrodes of the capacitor may be electrically connected to the driving transistor.

The driving transistor may include a semiconductor layer 203, a gate insulating layer 205, a gate electrode 207, and source/drain electrodes 212 and 211. The gate insulating layer 205 may be disposed between the semiconductor layer 203 and the gate electrode 207. An insulating layer that reduces or prevents penetration of moisture or impurities may be further included between the first substrate 200 and the semiconductor layer 203.

The semiconductor layer 203 may be made of an oxide semiconductor or silicon-based semiconductor material. For example, the semiconductor layer 203 may include a transparent oxide semiconductor material such as Indium-gallium-zinc-oxide (IGZO) or Indium-zinc-oxide (IZO). In addition, the semiconductor layer 203 may include a polysilicon semiconductor material.

The gate insulating layer 205 may be composed of a single layer or a plurality of layers of silicon oxide (SiOx) or silicon nitride (SiNx).

The gate electrode 207 may be disposed on the gate insulating layer 205. An area of the semiconductor layer 203 overlapping the gate electrode 207 in a vertical direction may be a channel area. A source area and a drain area may be respectively located on two opposing sides of the channel area.

A passivation layer 209 and an interlayer insulating layer 213 may be sequentially disposed on the gate electrode 207. The source electrode 212 and the drain electrode 211 may extend through the passivation layer 209 and the gate insulating layer 205. The source electrode 212 and the drain electrode 211 may be respectively disposed on two opposing sides of the gate electrode 207 while the gate electrode 207 is interposed therebetween, and may be connected to the source area and the drain area of the semiconductor layer 203, respectively.

The interlayer insulating layer 213 may cover transistors including the driving transistors, various signal lines, a capacitor, etc. which are disposed on the first substrate 200.

A protective layer 220 may be disposed on the interlayer insulating layer 213. The protective layer 220 may planarize a step generated by the underlying circuit element. The protective layer 220 may include an organic insulating material. The protective layer 220 may include a first protective layer 215 and a second protective layer 217 on the first protective layer 215. The second protective layer 217 may be directly on the first protective layer 215 such that the second protective layer 217 directly contacts the first protective layer 215. The protective layer 220 may also be referred to as a planarization layer.

The protective layer 220 may has a pixel contact hole defined therein extending through the first protective layer 215 and the second protective layer 217 while exposing a portion of a surface of the drain electrode 211 of the driving transistor DT. A pixel contact electrode 225 may fill the pixel contact hole while one surface thereof is in contact with the drain electrode 211.

A plurality of first electrodes 230 may be disposed on the protective layer 220 and may be respectively disposed in the first to third sub-pixels SP1, SP2, and SP3. Each first electrode 230 is on a corresponding pixel contact electrode 225 and is in contact with the pixel contact electrode 225 to electrically connect the driving transistor to the first electrode 230. In an embodiment, the first electrode 230 may have a multilayer structure. For example, the first electrode 230 may have a stack structure in which a lower layer 230a, an intermediate layer 230b, and an upper layer 230c are sequentially stacked. The lower layer 230a and the upper layer 230c may be disposed on lower and upper surfaces of the intermediate layer 230b, respectively. The intermediate layer 230b may have a second thickness different from a first thickness of each of the lower layer 230a and the upper layer 230c. For example, the first thickness may be smaller than the second thickness. The lower layer 230a and the upper layer 230c may have the same thickness. However, embodiments of the present disclosure are not limited thereto.

The first electrode 230 disposed in each of the first to third sub-pixels SP1, SP2, and SP3 may include a transparent metal oxide such as indium tin oxide (ITO) or indium zinc oxide (IZO). Alternatively, the first electrode 230 may have a single-layer or multi-layer structure including a reflective metal film made of silver (Ag), aluminum (Al), gold (Au), nickel (Ni), chromium (Cr), or a compound thereof. The first electrode 230 may also be referred to as a pixel electrode or an anode electrode.

The bank 235 may be disposed on the protective layer 220. The bank 235 serves to define each of the first to third sub-pixels SP1, SP2, and SP3. To this end, the bank 235 may be formed to cover an edge of the first electrode 230. In addition, the light-emitting area EA may be defined through a bank hole of the bank 235. For example, the light-emitting area EA may correspond to an area of the first electrode 230 exposed through the bank hole. The bank 235 may prevent light beams of different colors respectively emitted from adjacent sub-pixels from being mixed with each other. The bank 235 may include an organic insulating layer formed of a material such as polyimide or epoxy. However, embodiments of the present disclosure are not limited thereto. In an example, the bank 235 may include a material such as one of a black resin, graphite, or black ink.

A trench 240 may be defined in the bank 235 and the protective layer 220. The trench 240 may have a concave shape including a bottom surface and both opposing side surfaces extending from the bottom surface upwardly. The trench 240 may extend through the bank 235 and may be positioned at a boundary area between adjacent ones of the first to third sub-pixels SP1, SP2, and SP3, and may extend in the thickness direction of the protective layer 220. For example, the trench 240 may be defined in a boundary area between the first sub-pixel SP1 and the second sub-pixel SP2. For example, the trench 240 may be defined in a boundary area between the second sub-pixel SP2 and the third sub-pixel SP3. The trench 240 may be defined in the non-light-emitting area NEA. In one embodiment, the trench 240 extends through at least a portion of the protective layer 220. For example, the trench 240 extends through the entire thickness of the second protective layer 217 and extends through a portion of the first protective layer 217 without extending through the entire thickness of the first protective layer 217.

The light-emitting layer 250 may be disposed on the first electrodes 230. Thus, the light-emitting layer 250 is commonly disposed on multiple first electrodes 230 of different sub-pixels. In an example, the light-emitting layer 250 may include an organic material that emits white light.

The light-emitting layer 250 may include a multi-stack structure in which at least two stacks are stacked, wherein each stack includes a hole transport layer (HTL), a light-emitting material layer (EML), an electron transport layer (ETL), a hole blocking layer (HBL), a hole injecting layer (HIL), an electron blocking layer (EBL), and an electron injecting layer (EIL).

The light-emitting layer 250 may be disposed on an entirety of a surface of the display area DA. The light-emitting layer 250 may be disposed in the trench 240. For example, the light-emitting layer 250 may be disposed on the bottom surface of the trench 240 and on a top edge and a side surface of the bank layer 235 defining the trench 240. In this case, the light-emitting layer 250 may be absent in a partial area of the trench 240. Thus, a void may be defined in the trench. When the void is formed in the trench 240, the light-emitting layer 250 may be broken in the trench area. For example, a portion of the light-emitting layer 250 disposed on the bottom surface of the trench 240 and a portion of the light-emitting layer 250 disposed on a portion of the side surface of the trench close to the bottom surface may be disconnected from each other. When the trench 240 contains the void therein, a leakage current between the adjacent ones of the first to third sub-pixels SP1, SP2, and SP3 may be suppressed since the pathway for the current is broken due to the void.

The second electrode 260 may be disposed on the light-emitting layer 250. The second electrode 260 may be a common layer commonly disposed across the plurality of sub-pixels SP1, SP2, and SP3. The second electrode 260 may also be referred to as a common electrode or a cathode electrode. The second electrode 260 may include a semi-transmissive metal material. For example, the second electrode 260 may include magnesium (Mg), silver (Ag), or an alloy of magnesium (Mg) and silver (Ag).

A light-emitting element 270 may be configured to include the first electrode 230, the light-emitting layer 250, and the second electrode 260.

An encapsulation layer 280 may be disposed on the second electrode 260. The encapsulation layer 280 may seal the driving transistor and the light-emitting element disposed thereunder. The encapsulation layer 280 may prevent moisture or foreign substances from the outside from penetrating into the driving transistor and the light-emitting element disposed thereunder. In an example, the encapsulation layer 280 may include a multilayer structure including an inorganic insulating material layer and an organic insulating material layer.

The encapsulation layer 280 may be disposed on the first sub-pixel SP1, the second sub-pixel SP2, and the third sub-pixel SP3 and may have a flat upper surface.

A color conversion structure 290 may be disposed on the encapsulation layer 280. The color conversion structure 290 is over the light-emitting element 270 such that the light-emitting element 270 is between the color conversion structure 290 and the first substate 200. The color conversion structure 290 may include a first layer 281, a second layer 283 on the first layer 281, and a third layer 285 on the second layer 283.

The first layer 281 may be disposed on the flat upper surface of the encapsulation layer 280. The third layer 285 and the first layer 281 may be spaced apart from each other in the vertical direction. The second layer 283 may be disposed between the first layer 281 and the third layer 285.

Each of the first layer 281 and the third layer 285 of the color conversion structure 290 may be made of a metal material. For example, the metal material may include a metal material having high reflectivity, such as silver (Ag), a silver alloy, aluminum (Al), or an aluminum alloy.

Each of the first layer 281 and the third layer 285 may have a thickness of 20 nm to 50 nm. The first layer 281 and the third layer 285 may have the same thickness. Each of the first layer 281 and the third layer 285 may be formed to have a thickness sized such that each of the first layer 281 and the third layer 285 is capable of transmitting therethrough the light emitted from the light-emitting layer 250 and having increased light efficiency due to the micro-cavity effect. For example, when the thickness of each of the first layer 281 and the third layer 285 is greater than 50 nm, the light may be reflected therefrom toward the light-emitting layer 250. Accordingly, each of the first layer 281 and the third layer 285 may have a thickness that is less than 50 nm.

The second layer 283 disposed between the first layer 281 and the third layer 285 may include silicon oxide (SiOx). However, embodiments of the present disclosure are not limited thereto. For example, the second layer 283 disposed between the first layer 281 and the third layer 285 may be filled with air (or may be formed as an air layer).

The first layer 281 may extend across the first sub-pixel SP1, the second sub-pixel SP2, and the third sub-pixel SP3 and may be disposed on the flat upper surface of the encapsulation layer 280. The thickness of the first layer 281 is substantially the same across the first sub-pixel SP1, the second sub-pixel SP2, and the third sub-pixel SP3.

The second layer 283 may be configured to have different thicknesses in the respective the first sub-pixel SP1, the second sub-pixel SP2, and the third sub-pixel SP3 so that the first layer 281 and the third layer 285 are spaced apart from each other by different distances in the respective sub-pixels SP1, SP2, and SP3. That is, a first portion of the second layer 281 that is in the first sub-pixel SP1 has a first thickness, a second portion of the second layer 282 that is in the second sub-pixel SP2 has a second thickness, and a third portion of the third layer 283 that is in the third sub-pixel SP2 have different thicknesses. Accordingly, the second layer 283 may include steps 284a and 284b respectively formed in the boundary areas between the adjacent sub-pixels. For example, as the second layer 283 is configured to have different thicknesses in the first sub-pixel SP1 and the second sub-pixel SP2, a first step 284a may be formed in the boundary area between the first sub-pixel SP1 and the second sub-pixel SP2. In addition, as the second layer 283 is configured to have different thicknesses in the second sub-pixel SP2 and the third sub-pixel SP3, a second step 284b may be formed in the boundary area between the second sub-pixel SP2 and the third sub-pixel SP3.

The third layer 285 may be disposed on the second layer 283. As the second layer 283 has different thicknesses in different areas thereof respectively corresponding to the first to third sub-pixels SP1, SP2, and SP3, spacings between the third layer 285 and the first layer 281 in different areas thereof respectively corresponding to the first to third sub-pixels SP1, SP2, and SP3 may be different from each other. Thus, an upper surface of the second layer 285 corresponding to the first sub-pixel SP1 has a first height from the first substrate 200, an upper surface of the second layer 285 in the second sub-pixel SP2 has a second height from the first substrate 200 that is less than the first height, and an upper surface of the second layer 285 in the third sub-pixel SP3 has a third height from the first substrate 200 that is less than the second height.

For example, a first area 283a (e.g., the first portion) of the second layer 283 corresponding to the first sub-pixel SP1 may be constructed to have a first thickness, a second area 283b (e.g., the second portion) of the second layer 283 corresponding to the second sub-pixel SP2 may be constructed to have a second thickness, and a third area 283c (e.g., the third portion) of the second layer 283 corresponding to the third sub-pixel SP3 may be constructed to have a third thickness. For example, the first thickness may be the largest thickness, and the third thickness may be the smallest thickness. The second thickness may be smaller than the first thickness and greater than the third thickness.

In addition, a first portion 285a of the third layer 285 may vertically overlap the first sub-pixel SP1, a second portion 285b of the third layer 285 may vertically overlap the second sub-pixel SP2, and a third portion 285c of the third layer 285 may vertically overlap the third sub-pixel SP3. In one embodiment, the thickness of the first portion 285a, the second portion 285b, and the third portion 285c are substantially the same.

In an area corresponding to the first sub-pixel SP1, the first portion 285a of the third layer 285 and the first layer 281 may be spaced apart from each other by a first distance equal to the first thickness of the first area 283a of the second layer 283. In an area corresponding to the second sub-pixel SP2, the second portion 285b of the third layer 285 and the first layer 281 may be spaced apart from each other by a second distance equal to the second thickness of the second area 283b of the second layer 283. In an area corresponding to the third sub-pixel SP3, the third portion 285c of the third layer 285 and the first layer 281 may be spaced apart from each other by a third distance equal to the third thickness of the third area 283c of the second layer 283.

In an example, in an area corresponding to the first sub-pixel SP1, the first layer 281 and the first portion 285a of the third layer 285 may be spaced apart from each other by the first distance of 150 nm. In an area corresponding to the second sub-pixel SP2, the first layer 281 and the second portion 285b of the third layer 285 may be spaced apart from each other by the second distance of 100 nm. In an area corresponding to the third sub-pixel SP3, the first layer 281 and the third portion 285c of the third layer 285 may be spaced apart from each other by the third distance of 50 nm.

The light emitted from the light-emitting layer 250 may be converted into light beams of different colors after having passed through the first layer 281 to the third layer 285 of the color conversion structure 290 having different first to third thicknesses in the different areas corresponding to the first to third sub-pixels SP1, SP2, and SP3.

For example, in the display device according to the first embodiment of the present disclosure, a first spacing may be embodied as the encapsulation layer 280 between the second electrode 260 including the metal material of the light-emitting element 270 and the first layer 281 including the metal material in the color conversion structure 290, and a second spacing may be embodied as the second layer 283 between the third layer 285 including the metal material of the color conversion structure 290 and the first layer 281. In addition, the second spacing embodied as the second layer 283 of the color conversion structure 290 may be divided into different spacings with different first to third distances in different areas corresponding to the first to third sub-pixels SP1, SP2, and SP3.

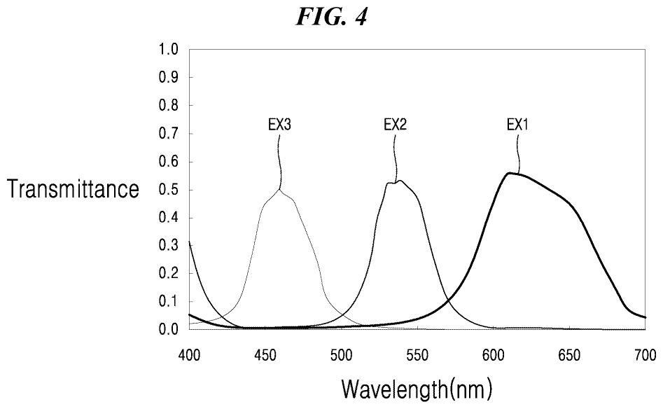

Accordingly, the light emitted from the light-emitting layer 250 commonly included in the first to third sub-pixels SP1, SP2, and SP3 may be converted into light beams of different colors after having passed through the first spacing and the second spacing. Hereinafter, the present disclosure will be described with reference to FIG. 4.

FIG. 4 is a graph showing transmittances through different distances between first and third layers of a color conversion structure in different areas corresponding to first to third sub-pixels in accordance with the first embodiment of the present disclosure. In FIG. 4, a horizontal axis represents a wavelength (nm) of light, and a vertical axis represents the transmittance as a relative value.

FIG. 4 is a graph obtained by measuring a wavelength range of light after the light emitted from a light-emitting layer 250 passes through a combination of the first spacing and the second spacing embodied as the second layer of the color conversion structure of the first embodiment of the present disclosure.

Referring to FIG. 4, it may be identified that light EX1 having transmitted through the area corresponding to the first sub-pixel SP1 is in a wavelength range of 600 nm to 670 nm. Accordingly, red light may be emitted from the area corresponding to the first sub-pixel SP1. In addition, it may be identified that the light EX2 having transmitted through the area corresponding to the second sub-pixel SP2 is in a wavelength range of 500 nm to 57 0 nm. Accordingly, green light may be emitted from the area corresponding to the second sub-pixel SP2. In addition, it may be identified that the light EX3 having transmitted through the area corresponding to the third sub-pixel SP3 is in a wavelength range of 400 nm to 495 nm. Accordingly, blue light may be emitted from the area corresponding to the third sub-pixel SP3.

A planarization film 291 may be disposed on the color conversion structure 290. The planarization film 291 may planarize a step caused due to the color conversion structure 290. Thus, the planarization film 281 may have portions with different thicknesses. A second substrate 293 may be disposed on the planarization film 291. The second substrate 293 may be referred to as a cover window, a window cover, or a cover glass. The second substrate 293 may include a glass substrate. However, embodiments of the present disclosure are not limited thereto. The second substrate 293 may include a plastic film.

In the display device according to the first embodiment of the present disclosure, the color conversion structure 290 may be disposed on and across different sub-pixels, such that light beams of different colors may be emitted from the different areas corresponding to the different sub-pixels without using the color filter. For example, the area corresponding to the first sub-pixel SP1 may emit red light, the area corresponding to the second sub-pixel SP2 may emit green light, and the area corresponding to the third sub-pixel SP3 may emit blue light.

Since the display device according to the first embodiment of the present disclosure does not use the color filter, the second substrate 293 may be disposed on one surface of the planarization film 291 so as to be in contact therewith. Accordingly, the display device may be slimmer than display devices with a color filter.

In addition, since light of different colors may be respectively emitted through the different areas of the color conversion structure 290 corresponding to the different sub-pixels even without using the color filter, there is an effect of providing a user with a high-resolution and high-quality image.

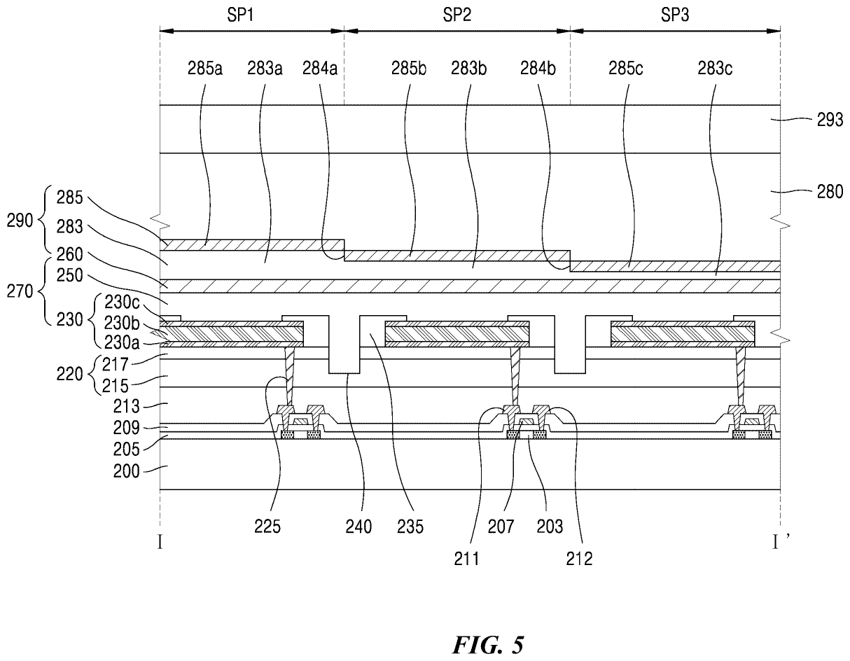

FIG. 5 is a cross-sectional view according to a second embodiment of the present disclosure. In FIG. 5, the same reference numerals as used in FIG. 3 are assigned to the same components as the components as described in FIG. 3, and a description thereof will be briefly made or omitted. In the second embodiment of the present disclosure according to FIG. 5, an example in which the display device operates in a top emission scheme will be described.

Referring to FIG. 5, the protective layer 220 may be disposed on the first to third sub-pixels SP1, SP2, and SP3 in which the driving transistors are respectively disposed. The protective layer 220 may include the first protective layer 215 and the second protective layer 217, and may include an organic insulating material.

A plurality of first electrodes 230 may be disposed on the protective layer 220 in a corresponding manner to the first to third sub-pixels SP1, SP2, and SP3. In an embodiment, the first electrode 230 may have a multilayer structure in which the lower layer 230a, the intermediate layer 230b, and the upper layer 230c are sequentially stacked. The bank 235 covering an edge of the first electrode 230 may be disposed.

The light-emitting layer 250 may be disposed on the first electrodes 230. In an example, the light-emitting layer 250 may include an organic material that emits white light.

The second electrode 260 may be disposed on the light-emitting layer 250. The second electrode 260 may be a common layer commonly disposed across the plurality of sub-pixels SP1, SP2, and SP3. The second electrode 260 may also be referred to as a common electrode or a cathode electrode. The second electrode 260 may be made of a metal material having high reflectivity, such as silver (Ag), a silver alloy, aluminum (Al), or an aluminum alloy. The second electrode 260 may have a thickness of 20 nm to 50 nm. In an example, the second electrode 260 may have a thickness smaller than 50 nm.

The light-emitting element 270 may include the first electrode 230, the light-emitting layer 250, and the second electrode 260.

The color conversion structure 290 may be disposed on the light-emitting element 270. In the display device according to the second embodiment of the present disclosure, the second electrode 260 of the light-emitting element 270 may act as the first layer of the color conversion structure 290. The second layer 283 and the third layer 285 may be disposed on the second electrode 260 acting as the first layer.

The third layer 285 may be made of a metal material. For example, the metal material may be made of a metal material having high reflectivity, such as silver (Ag), a silver alloy, aluminum (Al), or an aluminum alloy. The third layer 285 may have the same thickness as that of the second electrode 260. For example, the third layer 285 may have a thickness of 20 nm to 50 nm. The third layer 285 may have a thickness smaller than that of 50 nm.

The second layer 283 disposed between the second electrode 260 and the third layer 285 and may be embodied as a silicon oxide (SiOx) layer or an air layer.

The second layer 283 may have different thicknesses in different areas thereof respectively corresponding to the first to third sub-pixels SP1, SP2, and SP3 so that the first layer 281 and the third layer 285 may be spaced apart from each other by different distances in the different first to third areas corresponding to the first sub-pixel SP1, the second sub-pixel SP2, and the third sub-pixel SP3. For example, the first area 283a of the second layer 283 corresponding to the first sub-pixel SP1 may have the first thickness, and the third area 283c of the second layer 283 corresponding to the third sub-pixel SP3 may have the third thickness. In addition, the second area 283b of the second layer 283 corresponding to the second sub-pixel SP2 may have the second thickness that is relatively smaller than the first thickness and is relatively greater than the third thickness. The first thickness is greater than each of the second and third thicknesses.

As the second layer 283 continuously extends along the first to third sub-pixels SP1, SP2, and SP3, the steps 284a and 284b may be respectively formed in the boundary areas between adjacent ones of the first to third sub-pixels SP1, SP2, and SP3.

The third layer 285 may be disposed corresponding to each of the first to third areas 283a, 283b, and 283c of the second layer 283. For example, in the area corresponding to the first sub-pixel SP1, the second electrode 260 as the first layer and the first portion 285a of the third layer 285 may be spaced apart from each other by the first distance of 150 nm. In the area corresponding to the second sub-pixel SP2, the second electrode 260 as the first layer and the second portion 285b of the third layer 285 may be spaced apart from each other by the second distance of 100 nm. In the area corresponding to the third sub-pixel SP3, the second electrode 260 as the first layer and the third portion 285c of the third layer 285 may be spaced apart from each other by the third distance of 50 nm.

The encapsulation layer 280 may be disposed on the color conversion structure 290. The encapsulation layer 280 may planarize a step caused due to the color conversion structure 290 disposed thereunder. The encapsulation layer 280 may seal the driving transistor and the light-emitting element. In an example, the encapsulation layer 280 may include a multilayer structure including an inorganic insulating material layer and an organic insulating material layer.

The encapsulation layer 280 may be disposed on the first sub-pixel SP1, the second sub-pixel SP2, and the third sub-pixel SP3 and may have a flat upper surface.

The second substrate 293 may be disposed on the encapsulation layer 280. The second substrate 293 may be referred to as a cover window, a window cover, or a cover glass. The second substrate 293 may include a glass substrate. However, embodiments of the present disclosure are not limited thereto. The second substrate 293 may include a plastic film.

The light emitted from the light-emitting layer 250 may be converted into light beams of different colors after having passed through the first layer to the third layer of the color conversion structure 290 having different first to third thicknesses in the different areas corresponding to the first to third sub-pixels SP1, SP2, and SP3.

For example, in the display device according to the second embodiment of the present disclosure, the spacing may be embodied as the second layer 283 between the third layer 285 including the metal material of the color conversion structure 290 and the first layer embodied as the second electrode 260 of the light-emitting layer 250. In addition, the spacing embodied as the second layer 283 of the color conversion structure 290 may be divided into the different first to third distances in different areas corresponding to the first to third sub-pixels SP1, SP2, and SP3.

Accordingly, the light emitted from the light-emitting layer 250 commonly included in the first to third sub-pixels SP1, SP2, and SP3 may be converted into light beams of different colors after having passed through the spacing.

In the display device according to the second embodiment of the present disclosure, the color conversion structure 290 may be disposed on and across the sub-pixels, such that light beams of different colors may be emitted from the different areas corresponding to the different sub-pixels without using the color filter. For example, the area corresponding to the first sub-pixel SP1 may emit red light, the area corresponding to the second sub-pixel SP2 may emit green light, and the area corresponding to the third sub-pixel SP3 may emit blue light.

In addition, since the display device according to the second embodiment of the present disclosure may emit light beams of different colors in the different areas corresponding to the different sub-pixel even using the single spacing, the display device may be slimmed.

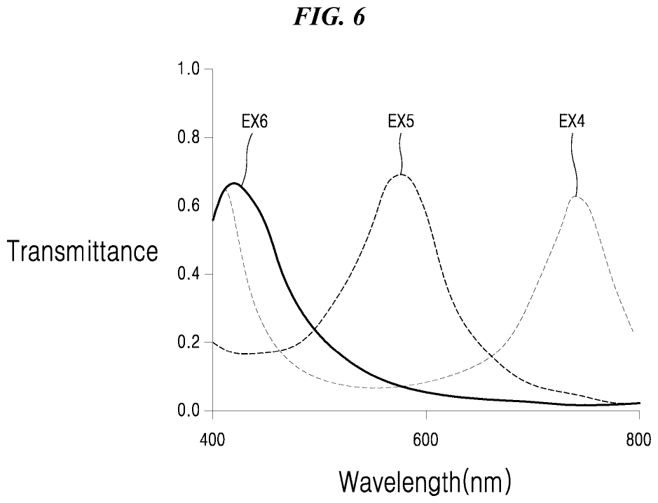

FIG. 6 is a graph showing transmittances through different distances between first and third layers of a color conversion structure in different areas corresponding to first to third sub-pixels in accordance with the second embodiment of the present disclosure. In FIG. 6, a horizontal axis represents a wavelength (nm) of light, and a vertical axis represents the transmittance as a relative value.

FIG. 6 is a graph obtained by measuring a wavelength range of light after the light emitted from the light-emitting layer 250 passes through the single spacing embodied as the second layer of the color conversion structure of the second embodiment of the present disclosure. In this regard, the color conversion structure 290 includes the first layer embodied as the second electrode 260. The second electrode 260 is made of silver (Ag) and has a thickness of 20 nm. In addition, the third layer 285 of the color conversion structure 290 is made of silver (Ag) and has a thickness of 20 nm in an entire area of the color conversion structure 290. In addition, the second layer 283 disposed between the second electrode 260 as the first layer of the color conversion structure 290 and the third layer 285 is embodied as an oxide film and has a thickness of 150 nm in the first area corresponding to the first sub-pixel SP1, a thickness of 100 nm in the second area corresponding to the second sub-pixel SP2, and a thickness of 50 nm in the third area corresponding to the third sub-pixel SP3.

Referring to FIG. 5 and FIG. 6, it may be identified that light EX4 having transmitted through the first area corresponding to the first sub-pixel SP1 is in a wavelength range of 630 nm to 750 nm. Accordingly, red light may be emitted from the first area corresponding to the first sub-pixel SP1.

In addition, it may be identified that the light EX5 having transmitted through the second area corresponding to the second sub-pixel SP2 is in a wavelength range of 500 nm to 570 nm. Accordingly, green light may be emitted from the second area corresponding to the second sub-pixel SP2.

In addition, it may be identified that the light EX6 having transmitted through the third area corresponding to the third sub-pixel SP3 is in a wavelength range of 400 nm to 495 nm. Accordingly, blue light may be emitted from the third area corresponding to the third sub-pixel SP3.

Since the display device according to the second embodiment of the present disclosure does not use the color filter, the second substrate 293 may be disposed on one surface (e.g., the lower surface) of the encapsulation layer 280 so as to be in contact therewith.

In the display device according to the second embodiment of the present disclosure, the second electrode 260 of the light-emitting element 270 acts as the first layer of the color conversion structure, thereby reducing the number of the process steps for forming the multilayer structure of the color conversion structure. In addition, the second electrode 260 acts as the first layer of the color conversion structure, such that the overall thickness of the display device may be reduced. The slim display device may be realized.

In addition, since light of a specific wavelength of a specific color may be emitted through the color conversion structure in each area corresponding to each sub-pixel, the color filter may be omitted. Accordingly, an expensive semiconductor exposure apparatus is not employed, such that an increase in a manufacturing cost is prevented, thereby reducing a cost of a final product. In addition, it is difficult to form a color filter pattern having a fine line width. However, according to the present disclosure, the color filter is omitted. Thus, an ultra-high resolution display device may be manufactured. In addition, omitting the color filter may result in simplifying the process such that the process optimization may be realized. In addition, since the color filter may be omitted, the amount of light may be prevented from being lost while passing through the color filter, thereby improving light efficiency.

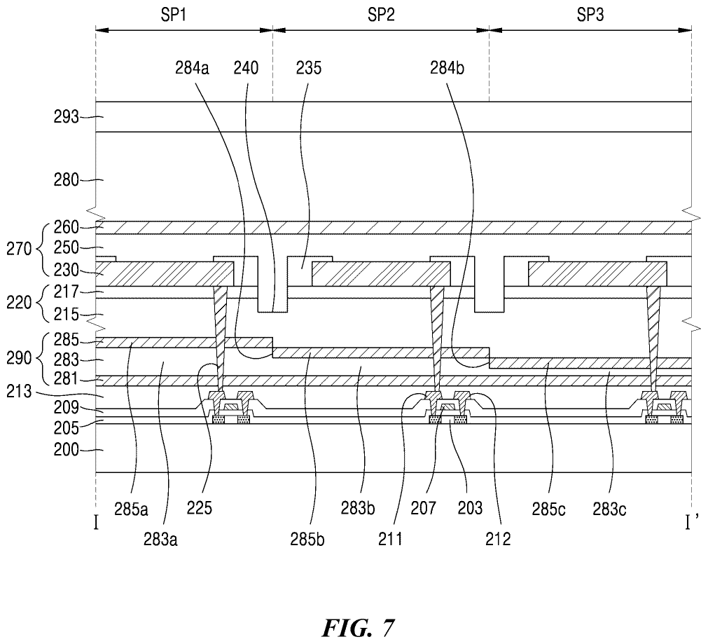

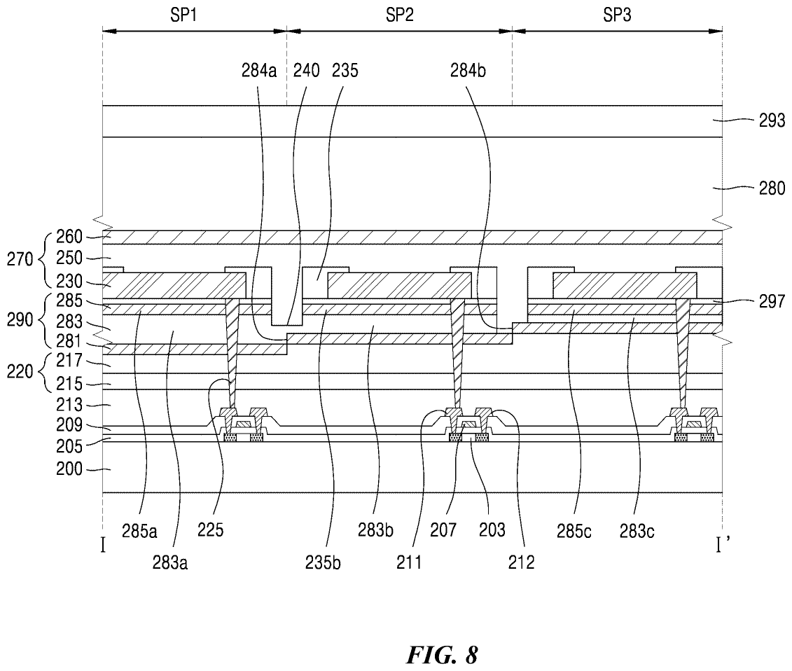

The color conversion structure may be applied not only to a display device operating in a top emission manner but also to a display device operating in a bottom emission manner. Hereinafter, the latter case will be described with reference to FIGS. 7 and 8.

In embodiments of the present disclosure according to FIGS. 7 and 8, an example in which the display device operates a bottom emission manner will be described.

FIG. 7 is a cross-sectional view according to a third embodiment of the present disclosure. In FIG. 7, the same reference numerals as used in FIG. 3 or FIG. 5 are assigned to the same components as the components as described in FIG. 3 or 5, and a description thereof will be briefly made or omitted.

Referring to FIG. 7, in the display device according to the third embodiment of the present disclosure, the first electrode 230 may be formed in a single layer structure. For example, the first electrode 230 may include a transparent metal oxide such as indium-tin-oxide (ITO) or indium-zinc-oxide (IZO). Alternatively, the first electrode 230 may include a reflective metal layer made of silver (Ag), aluminum (Al), gold (Au), nickel (Ni), chromium (Cr), or a compound thereof. However, the present disclosure is not limited thereto.

The light-emitting layer 250 and the second electrode 260 may be disposed on the first electrode 230. The encapsulation layer 280 may be disposed on the second electrode 260. The second substrate 293 may be in contact with one surface of the encapsulation layer 280.

In the display device according to the third embodiment of the present disclosure, the color conversion structure 290 may be disposed over the light-emitting element 270 emitting the light. For example, the color conversion structure 290 may be disposed under the first electrode 230 of the light-emitting element 270. The color conversion structure 290 may be disposed between the light-emitting element 270 and the first substrate 200. The color conversion structure 290 may be disposed under the first electrode 230 while covering the transistor, and may be disposed on one of multiple insulating layers stacked vertically. For example, the color conversion structure 290 may be disposed on the interlayer insulating layer 213. However, embodiments of the present disclosure are not limited thereto.

The color conversion structure 290 may include the first layer 281, the second layer 283, and the third layer 285 which are sequentially stacked (or deposited) on the interlayer insulating layer 213. The third layer 285 is on the second layer 283 such that the third layer 285 is farther from the first substrate 200 than the first layer 281 and the second layer 283. The first layer 281 and the third layer 285 may have the same thickness. For example, each of the first layer 281 and the third layer 285 may have a thickness of 20 nm to 50 nm.

The second layer 283 disposed between the first layer 281 and the third layer 285 may be constructed to have different thicknesses in different areas thereof respectively corresponding to the first to third sub-pixels SP1, SP2, and SP3 so that the first layer 281 and the third layer 285 may be spaced apart from each other by different distances in different areas of the color conversion structure 290 respectively corresponding to the first to third sub-pixels SP1, SP2, and SP3.

The third layer 285 may be disposed on the second layer 283. As the second layer 283 is constructed to have different thicknesses in different areas thereof respectively corresponding to the first to third sub-pixels SP1, SP2, and SP3, the distances between the third layer 285 and the first layer 281 in different areas of the color conversion structure 290 respectively corresponding to the first to third sub-pixels SP1, SP2, and SP3 may be different from each other.

In the display device according to the third embodiment of the present disclosure, a first spacing may be embodied as the protective layer 220 between the second electrode 260 including the metal material of the light-emitting element 270 and the third layer 285 including the metal material of the color conversion structure 290, and a second spacing may be embodied as the second layer 283 between the third layer 285 including the metal material of the color conversion structure 290 and the first layer 281 of the color conversion structure 290. In addition, the second spacing embodied as the second layer 283 of the color conversion structure 290 may be divided into different spacings with the different first to third distances in the different first to third areas corresponding to the first to third sub-pixels SP1, SP2, and SP3. Accordingly, the light emitted from the light-emitting layer 250 commonly included in the first to third sub-pixels SP1, SP2, and SP3 may be converted into light beams of different colors after having passed through the first spacing and the second spacing. Then, the light beams of different colors having passed through the first spacing and the second spacing may be emitted toward the first substrate 200.

FIG. 8 is a cross-sectional view according to a fourth embodiment of the present disclosure. In FIG. 8, the same reference numerals as used in FIG. 3 or 5 are assigned to the same components as the components described in FIG. 3 or 5, and a description thereof will be briefly made or omitted.

Referring to FIG. 8, a material of the first substrate 200 of the display device according to the fourth embodiment of the present disclosure may include glass. The first to third sub-pixels SP1, SP2, and SP3 in which the driving transistors are respectively disposed are formed on the first substrate 200. The protective layer 220 may be disposed on the first to third sub-pixels SP1, SP2, and SP3 in which the driving transistors are respectively disposed. The protective layer 220 may include the first protective layer 215 and the second protective layer 217, and may include an organic insulating material.

In an example, the second protective layer 217 may have different thicknesses in different areas thereof respectively corresponding to (or overlapping vertically) the first to third sub-pixels SP1, SP2, and SP3.

The color conversion structure 290 may be disposed on the second protective layer 217 such that the color conversion structure 290 is between the second protective layer 217 and the light-emitting element 270. The color conversion structure 290 may include the first layer 281, the second layer 283, and the third layer 285.

The first layer 281 may be disposed on the upper surface of the second protective layer 217. The third layer 285 and the first layer 281 may be spaced apart from each other. The second layer 283 may be disposed between the first layer 281 and the third layer 285.

The first electrode 230 may be disposed on the color conversion structure 290. The first electrode 230 may be formed in a single layer structure. For example, the first electrode 230 may include a transparent metal oxide such as indium-tin-oxide (ITO) or indium-zinc-oxide (IZO). Alternatively, the first electrode 230 may include a reflective metal layer made of silver (Ag), aluminum (Al), gold (Au), nickel (Ni), chromium (Cr), or a compound thereof. However, the present disclosure is not limited thereto.

In order to prevent the third layer 285 of the color conversion structure 290 from directly contacting the first electrode 230, a buffer insulating layer 297 may be disposed between the first electrode 230 and the third layer 285. The buffer insulating layer 297 may include aluminum oxide (Al2O3).

The second layer 283 may have different thicknesses in different areas thereof respectively corresponding to (or overlapping vertically) the first to third sub-pixels SP1, SP2, and SP3 so that the first layer 281 and the third layer 285 may be spaced apart from each other by different distances in different areas of the color conversion structure 290 respectively corresponding to the first sub-pixel SP1, the second sub-pixel SP2, and the third sub-pixel SP3.

The light emitted from the light-emitting layer 250 may be converted to light beams of the different colors after having passed through the first layer 281 to the third layer 285 of the color conversion structure 290 having the different first to third thicknesses in the first to third areas thereof corresponding to the first to third sub-pixels SP1, SP2, and SP3. Then, the light beams of the different colors may be emitted toward the first substrate 200.

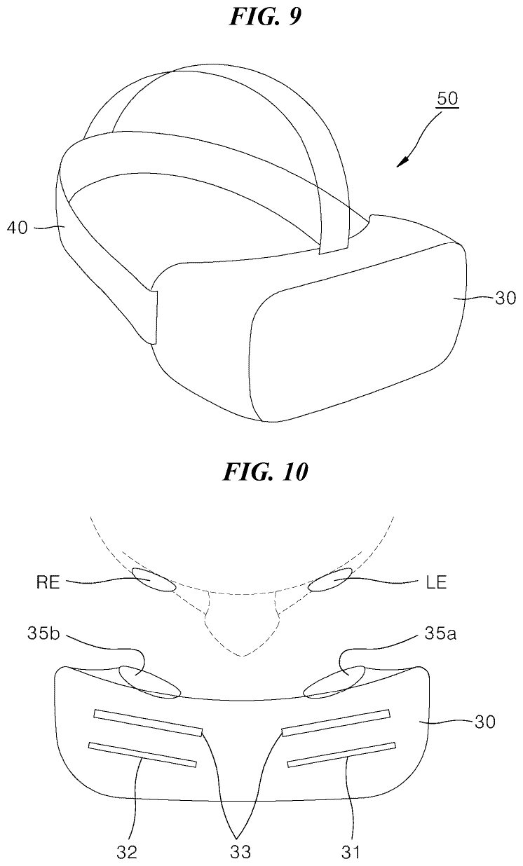

FIGS. 9 to 11 are diagrams of a head-mounted display apparatus including a display device according to an embodiment of the present disclosure

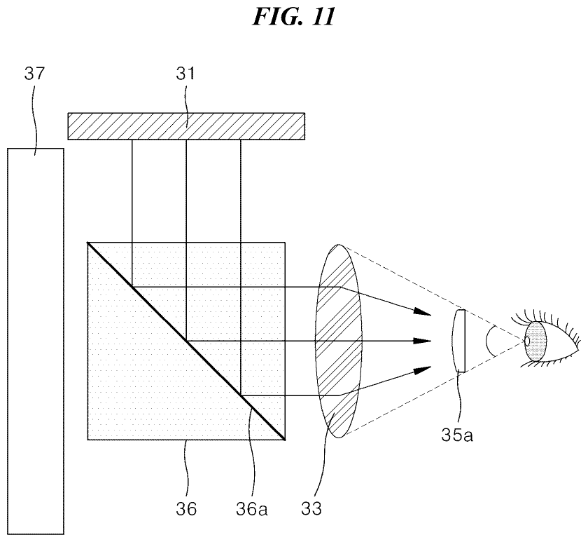

FIGS. 9 to 11 are diagrams of a head-mounted display apparatus including a display device according to an embodiment of the present disclosure. Specifically, FIG. 9 is a schematic perspective view of a head-mounted display apparatus including a display device according to an embodiment of the present disclosure, and FIG. 10 is a top view showing a head-mounted display apparatus implementing virtual reality. FIG. 11 is a side view showing a head-mounted display apparatus that implements augmented reality.

Referring to FIG. 9, the head-mounted display apparatus 50 including a display device according to an embodiment of the present disclosure may include a casing 30 and a head mounting band 40.

The casing 30 may receive therein components such as a display device, a lens array, an eyepiece, a sound device, an accelerometer, and a position sensor, etc. The head mounting band 40 is fixed to the casing 30. The head mounting band 40 is illustrated as being formed to surround an upper surface and two opposing side surfaces of the user's head. However, embodiments of the present disclosure are not limited thereto. The head mounting band 40 is used to secure the head-mounted display apparatus 50 to the user's head. In another example, the head mounting band 40 may be embodied as an eyeglass frame or a helmet-shaped structure that entirely surrounds the user's head.

The head-mounted display apparatus 50 may include the display device according to an embodiment of the present disclosure as described in FIG. 3, FIG. 5, FIG. 7 and FIG. 8, and may provide an image implementing virtual reality (VR) or an image implementing augmented reality (AR) to the user.

Referring to FIG. 10, the head-mounted display apparatus that implements virtual reality may include a display device for a left-eye (can also be referred to as a first display device) 31, a display device for a right-eye (can also be referred to as a second display device) 32, a lens array 33, and a left-eye eyepiece 35a and a right-eye eyepiece 35b. The display device for a left-eye 31 and the display device for a right-eye 32, the lens array 33, and the left-eye eyepiece 35a and the right-eye eyepiece 35b may be received in the casing 30.

The display device for a left-eye 31 and the display device for a right-eye 32 may display the same image. When the display device for a left-eye 31 and the display device for a right-eye 32 display the same image, the user may view the 2D image through the head-mounted display apparatus. Alternatively, the display device for a left-eye 31 may display an image for a left-eye, and the display device for a right-eye 32 may display an image for a right-eye that is different from the image for a left-eye. In this case, the user may view a three-dimensional image through the head-mounted display apparatus. Each of the display device for a left-eye 31 and the display device for a right-eye 32 may include the display device according to FIG. 3, FIG. 5, FIG. 7 and FIG. 8 as described above.

One of the lens array 33 may be spaced apart from each of the left-eye eyepiece 35a and the display device for a left-eye 31, and may be disposed between the left-eye eyepiece 35a and the display device for a left-eye 31. That is, one of the lens array 33 may be located in front of the left-eye eyepiece 35a and in rear of the display device for a left-eye 31. Furthermore, the other of the lens array 33 may be spaced away from each of the right-eye eyepiece 35b and the display device for a right-eye 32, and may be disposed between the right-eye eyepiece 35b and the display device for a right-eye 32. That is, the other of the lens array 33 may be located in front of the right-eye eyepiece 35b and in rear of the display device for a right-eye 32.

The lens array 33 may include, but is not limited to, a micro lens array. In one example, the lens array 33 may include a pin hole array. The image displayed from the display device for a left-eye 31 or the display device for a right-eye 32 may be visible to the user in an enlarged manner due to the lens array 33. The user's left-eye LE may be located in rear of the left-eye eyepiece 35a, and the user's right-eye RE may be located in rear of the right-eye eyepiece 35b.

Referring to FIG. 11, the head-mounted display apparatus that implements augmented reality includes the display device for a left-eye 31, the lens array 33, the left-eye eyepiece 35a, a transmissive and reflective portion 36, and a transmissive window 37. For convenience of illustration, FIG. 11 shows only a configuration related to the left-eye, and a configuration related to the right-eye is the same or similar to the configuration related to the left-eye. Additionally, the same drawing symbols as in FIG. 10 may represent the same components in FIG. 11

The display device for a left-eye 31, the lens array 33, the left-eye eyepiece 35a, the transmissive and reflective portion 36, and the transmissive window 37 are housed in casing 30 (see FIG. 9). The display device for a left-eye 31 may be disposed on one side of the transmissive and reflective portion 36, for example, on an upper side thereof so that the display device for a left-eye 31 does not block the transmissive window 37. Accordingly, the display device for a left-eye 31 may provide an image to the transmissive and reflective portion 36 without blocking an external background visible through the transmissive window 37.

The display device for a left-eye 31 may include the display device according to one embodiment of the present disclosure as shown in FIG. 3, FIG. 5, FIG. 7 and FIG. 8. The lens array 33 may be provided between the left-eye eyepiece 35a and the transmissive and reflective portion 36. The user's left-eye may be located in rear of the left-eye eyepiece 35a.

The transmissive and reflective portion 36 is disposed between the lens array 33 and the transmissive window 37. The transmissive and reflective portion 36 may include a transmissive and reflective surface 36a that transmits a portion of light therethrough and reflects the other portion of light therefrom. The transmissive and reflective surface 36a includes a semi-transmissive metal film. For example, the semi-transmissive metal film may be made of a semi-transmissive metal material such as magnesium (Mg), silver (Ag), or an alloy of magnesium (Mg) and silver (Ag). The transmissive and reflective surface 36a may be formed to allow the image displayed from the display device for a left-eye 31 to be directed to the lens array 33.

Therefore, the user may view both the external background visible through the transmissive window 37 and the image displayed from the display device for a left-eye 31. In other words, the user may view both the real background and the virtual image as one image in an overlapping manner. Thus, the augmented reality may be implemented.

The display device according to various aspects and embodiments of the present disclosure may be described as follows.

In one embodiment, a display device comprises: a first substrate including a plurality of sub-pixels; a plurality of first electrodes, each of the plurality of first electrodes on a corresponding sub-pixel from the plurality of sub-pixels; a light-emitting layer on the plurality of first electrodes; a second electrode on the light-emitting layer, and a color conversion structure over the plurality of sub-pixels, the color conversion structure having different thicknesses in each of the plurality of sub-pixels.

In one embodiment, the plurality of sub-pixels comprises a first sub-pixel emitting light of a first color, a second sub-pixel emitting light of a second color that is different from the first color, and a third sub-pixel emitting light of a third color that is different from both the first color and the second color.

In one embodiment, the color-conversion structure includes a first layer spaced apart from the second electrode, a second layer on the first layer, and a third layer on the second layer, wherein the second layer includes a first area that spaces apart the first layer and the third layer by a first distance, a second area that spaces apart the first layer and the third layer by a second distance that is different from the first distance, and a third area that spaces apart the first layer and the third layer by a third distance that is different from both the first distance and the second distance.

In one embodiment, the display device further comprises a planarization film on the third layer of the color-conversion structure and a second substrate on the planarization film such that the planarization film and second substrate are in contact with each other.

In one embodiment, the first area of the second layer overlaps the first sub-pixel, the second area of the second layer overlaps the second sub-pixel, and the third area of the second layer overlaps the third sub-pixel.

In one embodiment, the first distance is greater than each of the second distance and the third distance and the third distance is smaller than the second distance.

In one embodiment, a thickness of the first layer is the same as a thickness of the third layer.

In one embodiment, the thickness of the first layer and the thickness of the third layer is less than 50 nm.

In one embodiment, each of the first layer and the third layer includes silver, a silver alloy, aluminum, or an aluminum alloy, and the second layer includes an oxide or air.

In one embodiment, the color-conversion structure includes a third layer spaced apart from the second electrode and a second layer between the second electrode and the third layer, the second layer including a first area that spaces apart the second electrode and the third layer by a first distance, a second area that spaces apart the second electrode and the third layer by a second distance that is different from the first distance, and a third area that spaces apart the second electrode and the third layer by a third distance that is different from both the first distance and the second distance.

In one embodiment, the display device further comprises a planarization film on the third layer of the color-conversion structure and a second substrate on the planarization film such that the planarization film and second substrate are in contact with each other.

In one embodiment, a thickness of the second electrode and a thickness of the third layer are the same.

In one embodiment, the color-conversion structure includes a first layer under the plurality of first electrodes and spaced apart from the plurality of first electrodes, a second layer on the first layer, and a third layer on the second layer such that the third layer is farther from the first substrate than the first layer and the second layer, wherein the second layer includes a first area that spaces apart the first layer and the third layer by a first distance, a second area that spaces apart the first layer and the third layer by a second distance that is different from the first distance, and a third area that spaces apart the first layer and the third layer by a third distance that is different from both the first distance and the second distance.

In one embodiment, the display device further comprises an encapsulation layer on the second electrode and a second substrate on the encapsulation layer, wherein light generated from the light-emitting layer travels through the color-conversion structure and through the first substrate and is emitted out of the display device.

In one embodiment, the color-conversion structure includes a first layer under the plurality of first electrodes and spaced apart from the plurality of first electrodes, a second layer on the first layer, and a third layer on the second layer such that the third layer is farther from the first substrate than the first layer and the second layer, wherein the second layer includes a first area that spaces apart the first layer and the third layer by a first distance, a second area that spaces apart the first layer and the third layer by a second distance that is different from the first distance, and a third area that spaces apart the first layer and the third layer by a third distance that is different from both the first distance and the second distance, wherein the display device further comprises a buffer insulating layer between the plurality of first electrodes and the first layer.

In one embodiment, the buffer insulating layer is between the plurality of first electrodes and the first layer, and the buffer insulating layer includes aluminum oxide.

In one embodiment, a display device comprises: a substrate; a plurality of transistors on the substrate; a plurality of light-emitting elements electrically connected to the plurality of transistors, the plurality of light-emitting elements including a first light-emitting element and a second light-emitting element that emit light of a same color; and a color conversion structure on the plurality of light-emitting elements, the color conversion structure including metal and comprising: a first portion on the first light-emitting element and having a first thickness, the first portion converting the light emitted by the first light-emitting element into a first color; and a second portion on the second light-emitting element and having a second thickness that is different from the first thickness, the second portion converting the light emitted by the second light-emitting element into a second color that is different from the first color.

In one embodiment, the plurality of light-emitting elements further include a third light-emitting element that emits light of the same color as the first light-emitting element and the second light-emitting element, and the color-conversion structure further comprises a third portion on the third light-emitting element and having a third thickness that is different from the first thickness and the second thickness, the third portion converting the light emitted by the third light-emitting element into a third color that is different from the first color and the second color.

In one embodiment, the color-conversion structure comprises a first metal layer included in the first portion, the second portion, and the third portion of the color-conversion structure, a second layer on the first metal layer, the second layer included in the first portion, the second portion, and the third portion of the color-conversion structure, and a second metal layer on the second layer, the second metal layer included in the first portion, the second portion, and the third portion of the color-conversion structure.

In one embodiment, a thickness of the first metal layer is the same as a thickness of the second metal layer.

In one embodiment, a first portion of the second layer that is included in the first portion of the color-conversion structure has a first thickness, a second portion of the second layer that is included in the second portion of the color-conversion structure has a second thickness that is less than the first thickness, and a third portion of the second layer that is included in the third portion of the color-conversion structure has a third thickness that is less than the second thickness.

In one embodiment, an upper surface of the second metal layer in the first portion has a first height from the substrate, an upper surface of the second metal layer in the second portion has a second height from the substrate that is less than the first height, and an upper surface of the second metal layer in the third portion has a third height from the substrate that is less than the second height.

In one embodiment, the color-conversion structure is over the plurality of light-emitting elements such that the plurality of light-emitting elements are between the color-conversion structure and the substrate.

In one embodiment, the color-conversion structure is under the plurality of light-emitting elements such that the color-conversion structure is between the plurality of light-emitting elements and the substrate.

In one embodiment, the display device further comprises an insulating layer between the plurality of light-emitting elements and the color-conversion structure.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display device comprising:
a first substrate including a plurality of sub-pixels;
a plurality of first electrodes, each of the plurality of first electrodes on a corresponding sub-pixel from the plurality of sub-pixels;
a light-emitting layer on the plurality of first electrodes;
a second electrode on the light-emitting layer, and
a color conversion structure over the plurality of sub-pixels, the color conversion structure having different thicknesses in each of the plurality of sub-pixels.

2. The display device of claim 1, wherein the plurality of sub-pixels comprises:
a first sub-pixel emitting light of a first color;
a second sub-pixel emitting light of a second color that is different from the first color; and
a third sub-pixel emitting light of a third color that is different from both the first color and the second color.

3. The display device of claim 2, wherein the color conversion structure includes:
a first layer spaced apart from the second electrode;
a second layer on the first layer; and
a third layer on the second layer,
wherein the second layer includes:
a first area that spaces apart the first layer and the third layer by a first distance;
a second area that spaces apart the first layer and the third layer apart by a second distance that is different from the first distance; and
a third area that spaces apart the first layer and the third layer by a third distance that is different from both the first distance and the second distance.

4. The display device of claim 3, wherein the display device further comprises:
a planarization film on the third layer of the color conversion structure; and
a second substrate on the planarization film such that the planarization film and second substrate are in contact with each other.

5. The display device of claim 3, wherein the first area of the second layer overlaps the first sub-pixel, the second area of the second layer overlaps the second sub-pixel, and the third area of the second layer overlaps the third sub-pixel.

6. The display device of claim 3, wherein the first distance is greater than each of the second distance and the third distance and the third distance is smaller than the second distance.

7. The display device of claim 3, wherein a thickness of the first layer is a same as a thickness of the third layer.

8. The display device of claim 7, wherein the thickness of the first layer and the thickness of the third layer is less than 50 nm.

9. The display device of claim 3, wherein each of the first layer and the third layer includes silver, a silver alloy, aluminum, or an aluminum alloy and the second layer includes an oxide or air.

10. The display device of claim 1, wherein the color conversion structure includes:
a third layer spaced apart from the second electrode; and
a second layer between the second electrode and the third layer, the second layer including:
a first area that spaces apart the second electrode and the third layer by a first distance;
a second area that spaces apart the second electrode and the third layer by a second distance that is different from the first distance; and
a third area that spaces apart the second electrode and the third layer by a third distance that different from both the first distance and the second distance.

11. The display device of claim 10, wherein the display device further comprises:
a planarization film on the third layer of the color conversion structure; and
a second substrate on the planarization film such that the planarization film and second substrate are in contact with each other.

12. The display device of claim 10, wherein a thickness of the second electrode and a thickness of the third layer are a same.

13. The display device of claim 1, wherein the color conversion structure includes:
a first layer under the plurality of first electrodes and spaced apart from the plurality of first electrodes;
a second layer on the first layer; and
a third layer on the second layer such that the third layer is farther from the first substrate than the first layer and the second layer,
wherein the second layer includes:
a first area that spaces apart the first layer and the third layer by a first distance;
a second area that spaces apart the first layer and the third layer by a second distance that is different from the first distance; and
a third area that spaces apart the first layer and the third layer by a third distance that is different from both the first distance and the second distance.

14. The display device of claim 13, wherein the display device further comprises:
an encapsulation layer on the second electrode; and
a second substrate on the encapsulation layer,
wherein light generated from the light-emitting layer travels through the color conversion structure and through the first substrate and is emitted out of the display device.

15. The display device of claim 1, wherein the color conversion structure includes:
a first layer under the plurality of first electrodes and spaced apart from the plurality of first electrodes;
a second layer on the first layer; and
a third layer on the second layer such that the third layer is farther from the first substrate than the first layer and the second layer,
wherein the second layer includes:
a first area that spaces apart the first layer and the third layer by a first distance;
a second area that spaces apart the first layer and the third layer by a second distance that is different from the first distance; and
a third area that spaces apart the first layer and the third layer by a third distance that is different from both the first distance and the second distance,
wherein the display device further comprises a buffer insulating layer between the plurality of first electrodes and the first layer.

16. The display device of claim 15, wherein the buffer insulating layer is between the plurality of first electrodes and the third layer, and the buffer insulating layer includes aluminum oxide.

17. A display device comprising:
a substrate;
a plurality of transistors on the substrate;
a plurality of light-emitting elements electrically connected to the plurality of transistors, the plurality of light-emitting elements including a first light-emitting element and a second light-emitting element that emit light of a same color; and
a color conversion structure on the plurality of light-emitting elements, the color conversion structure including metal and comprising:
a first portion on the first light-emitting element and having a first thickness, the first portion converting the light emitted by the first light-emitting element into a first color; and
a second portion on the second light-emitting element and having a second thickness that is different from the first thickness, the second portion converting the light emitted by the second light-emitting element into a second color that is different from the first color.

18. The display device of claim 17, wherein the plurality of light-emitting elements further include a third light-emitting element that emits light of the same color as the first light-emitting element and the second light-emitting element, and the color conversion structure further comprises:
a third portion on the third light-emitting element and having a third thickness that is different from the first thickness and the second thickness, the third portion converting the light emitted by the third light-emitting element into a third color that is different from the first color and the second color.

19. The display device of claim 18, wherein the color conversion structure comprises:
a first metal layer included in the first portion, the second portion, and the third portion of the color conversion structure;
a second layer on the first metal layer, the second layer included in the first portion, the second portion, and the third portion of the color conversion structure; and
a second metal layer on the second layer, the second metal layer included in the first portion, the second portion, and the third portion of the color conversion structure.

20. The display device of claim 19, wherein a thickness of the first metal layer is a same as a thickness of the second metal layer.

21. The display device of claim 20, wherein a first portion of the second layer that is included in the first portion of the color conversion structure has a first thickness, a second portion of the second layer that is included in the second portion of the color conversion structure has a second thickness that is less than the first thickness, and a third portion of the second layer that is included in the third portion of the color conversion structure has a third thickness that is less than the second thickness.

22. The display device of claim 21, wherein an upper surface of the second metal layer in the first portion has a first height from the substrate, an upper surface of the second metal layer in the second portion has a second height from the substrate that is less than the first height, and an upper surface of the second metal layer in the third portion has a third height from the substrate that is less than the second height.

23. The display device of claim 21, wherein the color conversion structure is over the plurality of light-emitting elements such that the plurality of light-emitting elements are between the color conversion structure and the substrate.

24. The display device of claim 21, wherein the color conversion structure is under the plurality of light-emitting elements such that the color conversion structure is between the plurality of light-emitting elements and the substrate.

25. The display device of claim 24, further comprising:
an insulating layer between the plurality of light-emitting elements and the color conversion structure.
